(19) United States
(12) Patent Application Publication
(10) Pub. No.: US 2026/0010066 A1
(43) Pub. Date: Jan. 8, 2026

(54) OPTICAL STRUCTURE AND METHOD OF MANUFACTURING THE SAME

(71) Applicant: SK hynix Inc., Icheon-si Gyeonggi-do (KR)

(72) Inventor: Tae Joong HA, Icheon-si Gyeonggi-do (KR)

(73) Assignee: SK hynix Inc., Icheon-si Gyeonggi-do (KR)

(21) Appl. No.: 18/933,422

(22) Filed: Oct. 31, 2024

(30) Foreign Application Priority Data
Jul. 3, 2024 (KR) 10-2024-0087496

(51) Int. Cl. G03F 1/62

(52) U.S. Cl. CPC G03F 1/62

(57) ABSTRACT

An optical structure includes a porous membrane and a border portion. The porous membrane includes at least one light-transmissive membrane layer and includes a plurality of pores that is randomly arranged in the membrane layer. The border portion is positioned at a bottom edge of the porous membrane to support the porous membrane.

### CROSS-REFERENCES TO RELATED APPLICATION

The present application claims priority under 35 U.S.C. § 119(a) to Korean patent application number 10-2024-0087496, filed on Jul. 3, 2024, in the Korean Intellectual Property Office, which application is incorporated herein by reference in its entirety.

### BACKGROUND

### 1. Technical Field

Various embodiments of the present disclosure relate to an optical structure and a method of manufacturing the same, and more particularly to an optical structure including a pellicle structure used to protect a photomask and a method of manufacturing the optical structure.

### 2. Related Art

In general, a lithography process using an extreme ultraviolet (EUV) light (hereinafter, EUV lithography process) may use reflective optics and reflective photomasks. To prevent contamination of the reflective photomask, an optical structure configured to protect the reflective photomask may be used.

The optical structure used in the EUV lithography process may include an optical membrane configured to transmit light, e.g., EUV, a support structure configured to support the optical membrane, and a frame configured to connect the optical membrane with the reflective photomask. A conventional optical membrane may have a hermetically sealed structure. As a result, pressure imbalances may cause the membrane to deform or break.

### SUMMARY

According to example embodiments, there may be provided an optical structure. The optical structure may include a porous membrane and a border portion. The porous membrane may include at least one light-transmissive membrane layer. A plurality of pores may be randomly arranged in the membrane layer. The border portion may be positioned at a bottom edge of the porous membrane to support the porous membrane.

According to example embodiments, there may be provided a method of manufacturing an optical structure. A porous membrane including a plurality of pores may be formed over a wafer. The plurality of pores may be randomly arranged. A central region of the wafer may be etched to form a border portion configured to support the porous membrane.

According to example embodiments, there may be provided a method of manufacturing an optical structure. In the method of manufacturing the optical structure, a support layer may be prepared. A first preliminary membrane layer may be formed over the support layer. The first preliminary membrane layer may be porously treated to form a porous membrane including a plurality of pores that is randomly arranged, wherein at least one of a cross-sectional structure and a planar structure of a pore, among cross-sectional structures of the plurality of pores and planar structures of the plurality of pores, is non-uniform. The porously treating of the preliminary membrane layer may include at least one of a process for implanting and diffusing impurities at a high temperature to generate a pore barrier or a tunneling path in the preliminary membrane layer, a process for thermally treating at a high temperature to generate crystal defects in the preliminary membrane layer, and a process for implanting impurities to generate a damage on a surface of the preliminary membrane layer.

### BRIEF DESCRIPTION OF THE DRAWINGS

The above and another aspects, features and advantages of the subject matter of the present disclosure will be more easily understood from the following detailed description taken in conjunction with the accompanying drawings, in which:

FIG. 1 is a block diagram illustrating a photolithography apparatus in accordance with example embodiments;

FIG. 2 is a cross-sectional view illustrating a mask assembly in FIG. 1;

FIG. 3 is a detailed cross-sectional view illustrating an optical structure in accordance with example embodiments;

FIG. 4 is a plan view illustrating a porous membrane in accordance with example embodiments;

FIGS. 5 to 7 are cross-sectional views illustrating a method of manufacturing the pellicle structure in FIG. 3;

FIG. 8 is a cross-sectional view illustrating a method of manufacturing a pellicle structure in accordance with example embodiments;

FIG. 9 is a cross-sectional view illustrating a pellicle structure in accordance with example embodiments;

FIG. 10 is a cross-sectional view illustrating a pellicle structure in accordance with example embodiments;

FIG. 11 is a cross-sectional view illustrating a pellicle structure in accordance with example embodiments;

FIGS. 12 to 14 are cross-sectional views illustrating a method of manufacturing the pellicle structure in FIG. 11;

FIG. 15 is a cross-sectional view illustrating a method of manufacturing a pellicle structure in accordance with example embodiments;

FIG. 16 is a cross-sectional view illustrating a pellicle structure in accordance with example embodiments; and

FIGS. 17 to 19 are cross-sectional views illustrating a method of manufacturing the pellicle structure in FIG. 16.

### DETAILED DESCRIPTION

Various embodiments of the present disclosure will be described in greater detail with reference to the accompanying drawings. The drawings are schematic illustrations of various embodiments and intermediate structures. As such, variations from the configurations and shapes of the illustrations as a result, for example, of manufacturing techniques and/or tolerances, are to be expected. Thus, the described embodiments should not be construed as being limited to the particular configurations and shapes illustrated herein but may include deviations in configurations and shapes which do not depart from the technical concepts and scope of the embodiments of the present disclosure as defined in the appended claims.

Some embodiments are described herein with reference to cross-section and/or plan illustrations of the example embodiments. However, the embodiments should not be construed as limiting the disclosed inventive concepts. Although a few embodiments will be shown and described, it will be appreciated by those of ordinary skill in the art that changes may be made in these embodiments without departing from the principles and technical concept of the present disclosure.

As used herein, the term “configured” refers to a size, shape, material composition, orientation, and arrangement of one or more of at least one structure and at least one apparatus facilitating operation of one or more of the structure and the apparatus in a pre-determined way.

As used herein, the terms “vertical,” “longitudinal,” “horizontal,” and “lateral” are in reference to a major plane of a structure and are not necessarily defined by earth's gravitational field. A “horizontal” or “lateral” direction is a direction that is substantially parallel to the major plane of the structure, while a “vertical” or “longitudinal” direction is a direction that is substantially perpendicular to the major plane of the structure. The major plane of the structure is defined by a surface of the structure having a relatively large area compared to other surfaces of the structure. With reference to the figures, a “horizontal” or “lateral” direction may be perpendicular to an indicated “Z” axis, and may be parallel to an indicated “X” axis and/or parallel to an indicated “Y” axis; and a “vertical” or “longitudinal” direction may be parallel to an indicated “Z” axis, may be perpendicular to an indicated “X” axis, and may be perpendicular to an indicated “Y” axis.

As used herein, spatially relative terms, such as “beneath,” “below,” “bottom,” “above,” “upper,” “front,” “rear,” “left,” “right,” and the like, may be used for ease of description to describe one element's or feature's relationship to another element(s) or feature(s) as illustrated in the figures. Unless otherwise specified, the spatially relative terms are intended to encompass different orientations of the materials in addition to the orientation depicted in the figures. For example, if materials in the figures are inverted, elements described as “below” or “beneath” or “under” or “on bottom of” other elements or features would then be oriented “above” or “on upper of” the other elements or features. Thus, the term “below” may encompass both an orientation of above and below, depending on the context in which the term is used, which will be evident to one of ordinary skill in the art. The materials may be otherwise oriented (e.g., rotated 90 degrees, inverted, flipped) and the spatially relative descriptors used herein interpreted accordingly.

Example embodiments provide an optical structure including a pellicle structure configured to improve exposure characteristics.

Example embodiments also provide a method of manufacturing the above-mentioned optical structures.

According to example embodiments, since the membrane may have the porous structure, a pressure imbalance may not be generated in the membrane. Thus, deformation or breakage of the membrane due to pressure imbalance may be prevented. In particular, since the pores of the porous membrane may be randomly and irregularly arranged, a deformation of the exposure pattern due to regular scattering may be suppressed.

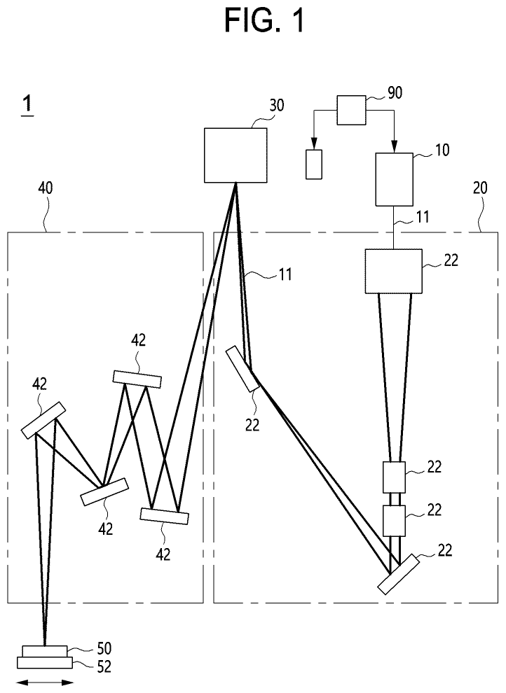

FIG. 1 is a block diagram illustrating a photolithography apparatus in accordance with example embodiments.

Referring to FIG. 1, a lithography apparatus 1 may include a light source unit 10, a condenser unit 20, a projection unit 40, and a control unit 90.

The light source unit 10 may generate a light 11 for performing a lithography process. The light 11 may be an EUV light having a wavelength of about 10 nm to about 14 nm. The light 11 generated by the light source unit 10 may be provided to the condenser unit 20.

The condenser unit 20 may focus the light 11 onto a mask assembly 30. The condenser unit 20 may include at least one lens structure 22. The lens structure 22 may include at least one of a lens, a mirror, and any combination thereof.

The mask assembly 30 may include a photomask and an optical structure. The optical structure may be disposed on a light incident surface of the photomask. The mask assembly 30 may further include a stage configured to move the photomask.

The light 11 incident to the mask assembly 30 may be reflected by the mask assembly 30. The light 11 may then be incident to the projection portion 40. The projection portion 40 may project a patterned image of the mask assembly 30 onto a target substrate 50. The target substrate 50 may be a wafer on which an integrated circuit is to be formed. For example, the target substrate 50 may include a photoresist film responsive to the light 11. The projection unit 40 may include at least one projection optic 42. The projection optic 42 may include at least one of a lens and a mirror. The projection optic 42 may use the light 11 reflected from the mask assembly 30 to reduce the patterned image on the mask assembly 30 to a predetermined magnification (for example, 4×, 6×, or 8×) and may project the reduced pattern image onto the target substrate 50.

A reference numeral 52 may be a substrate stage. The substrate stage 52 may move the target substrate 50 to change an exposure area (or exposure location) of the target substrate 50.

The control unit 90 may control all operations of the light source unit 10, the condenser unit 20, the mask assembly 40, the projection unit 50 and the substrate stage 52.

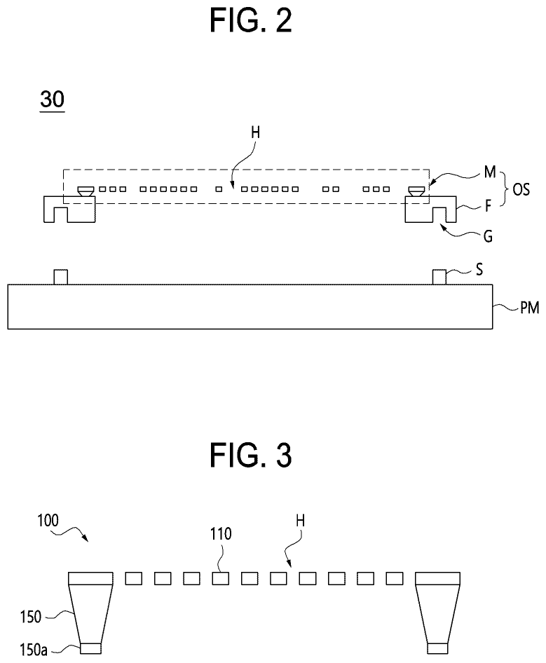

FIG. 2 is a cross-sectional view illustrating the mask assembly in FIG. 1.

Referring to FIG. 2, the mask assembly 30 may include a photomask PM and an optical structure OS.

The optical structure OS may be disposed over the photo mask PM. The optical structure OS may include, for example, a pellicle structure M and a frame F. The pellicle structure M may include a porous membrane and a border portion. For example, the porous membrane may include a plurality of pores H that are randomly or irregularly arranged. The border portion may support the porous membrane. A thickness of the border portion may vary. The pellicle structure M may protect the photomask PM while transmitting a light incident through the photomask PM.

The frame F may be provided at a bottom edge of the pellicle structure M to support the pellicle structure M. For example, a groove G may be provided on a bottom surface of the frame F, and a stud s may be provided on an upper surface of the photomask PM to be inserted into the groove G. That is, the stud s of the photomask PM may be inserted into the groove G of the frame F so that the optical structure OS may be combined with and fixed to the photomask PM.

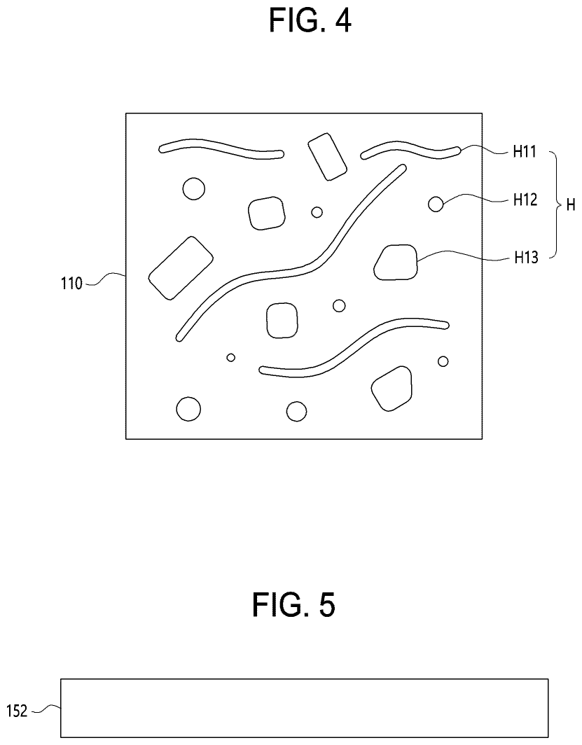

FIG. 3 is a detailed cross-sectional view illustrating a pellicle structure in accordance with example embodiments. FIG. 4 is a plan view illustrating a porous membrane in accordance with example embodiments.

Referring to FIG. 3, the pellicle structure 100 of example embodiments may include a porous membrane 110 and a border portion 150.

The porous membrane 110 may transmit a light passing through the photomask PM. For example, the porous membrane 110 may include at least one of light-transmissive membrane layer, for example, single crystalline silicon, polysilicon, amorphous silicon, SiO2, SiC, SiN, SiOCN, SiON, SiOC, MoSi2, Mo2C, MoC, a porous material layer, an impurity-containing material layer, a carbon nanotube (or nanowire) layer, and a metal-containing material layer. However, the embodiments are not limited thereto. For example, the porous membrane 110 may include a composite layer including two or more materials selected from the above-mentioned materials.

The porous membrane 110 may include a plurality of pores H arranged randomly. The plurality of pores H may have the same or different diameters.

Referring to FIG. 4, the pores H of the porous membrane 110 may have various planar structures. For example, the pores H of the porous membrane 110 may have the planar shape of a line structure H11, a quasi-circular structure H12, and a polygonal structure H13.

The optical structure 100 having the porous membrane 110 does not have a closed structure due to the plurality of pores H. That is, the optical structure 100 may have an opened structure. Thus, deformation or breakage of the porous membrane 110 due to pressure imbalance may be prevented.

Additionally, the pores H may be randomly arranged in the membrane 110 rather than uniformly arranged. Because the randomly arranged pores H may lack uniformity, the pores H may reduce an intensity of anomalous light sources that are enhanced by the scattered light being uniform. Accordingly, the pores H may reduce an influence of the anomalous light source to allow a desired light to be accurately incident on the photomask PM.

The border portion 150 may be disposed at an edge portion of a bottom surface of the porous membrane 110. The border portion 150 may support the porous membrane 110. The border portion 150 may attach the porous membrane 110 to the upper surface of the photomask PM while providing a certain gap between the surface of the photomask PM and the porous membrane 110. That is, the porous membrane 110 may be secured to the photomask PM through the border portion 150.

In example embodiments, the border portion 150 may be, but is not limited to, a part of a wafer. When the border portion 150 is a part of the wafer, the border portion 150 may be formed by partially removing the wafer.

In example embodiments, the border portion 150 may have a width that gradually increases when the width is measured closer to the porous membrane 110, i.e., from bottom to top, but the embodiments are not limited thereto. For example, the border portion 150 may have a width that gradually decreases when the width is measured closer to the porous membrane 110. Alternatively, the border portion 150 may have a uniform width.

Additionally, a supporting structure (not shown) may be disposed on the upper surface or the bottom surface of the porous membrane 110. For example, a deflection of the porous membrane 110 due to the loading of the porous membrane 110 may be prevented by the supporting structure.

A reference numeral 150a may indicate an adhesive pattern attached to a bottom surface of the border portion 150.

FIGS. 5 to 7 are cross-sectional views illustrating a method of manufacturing the optical structure in FIG. 3.

First, referring to FIG. 5, as a support layer, a wafer 152 may be provided. The wafer 152 may be formed into the border portion 150 through a subsequent process. The wafer 152 may be a silicon (Si) wafer, a silicon germanium (SiGe) wafer, a gallium arsenide wafer, or an SOI wafer, but the material, structure, etc., of the wafer 152 is not specifically limited thereto.

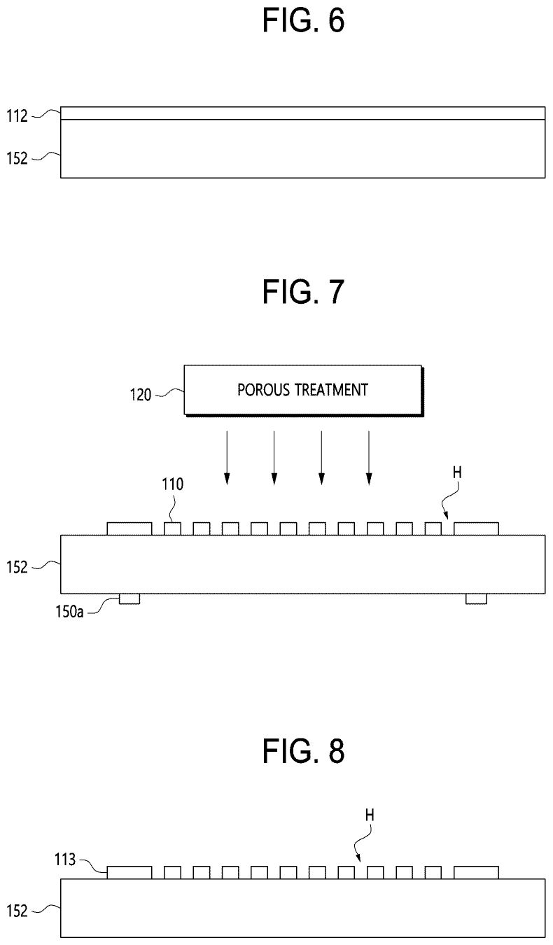

Referring to FIG. 6, a preliminary membrane layer 112 may be formed on an upper surface of the wafer 152. In example embodiments, the preliminary membrane layer 112 may have a non-porous state at the time of deposition. The preliminary membrane layer 112 may include a single element, such as silicon, germanium, gallium arsenide (GaAs), silicon carbide (SiC), or a compound thereof, for example. Furthermore, the preliminary membrane layer 112 may include a Mo-containing compound, such as MoSi2, MoC, and Mo2C, a metallic compound, or a silicon compound.

Referring to FIG. 7, a porous treatment 120 may be performed to the preliminary membrane layer 112 (refer to FIG. 6) to form a porous membrane layer 110 including a plurality of pores H that are randomly arranged (hereinafter, randomly arranged pores H). In example embodiments, the porous treatment 120 may be a process for changing properties of the preliminary membrane layer 112 to generate the randomly arranged pores H in the preliminary membrane layer 112.

For example, the porous treatment 120 may include at least one of a process for ion implanting impurities and diffusing impurities at a high temperature (or high concentrations of impurities) to generate a pore barrier or tunneling path in the preliminary membrane layer 112. Further, the porous treatment 120 may include at least one type of thermal treatment to generate crystal defects in the preliminary membrane layer 112, a process for ion implanting impurities to generate damage on the surface of the preliminary membrane layer 112, and a process for transcribing a pore pattern in the preliminary membrane layer 112 using a mask for forming pores.

In example embodiments, the preliminary membrane layer 112 may be formed of the same semiconductor material, such as a wafer 152. Then, the impurities may be implanted into the preliminary membrane layer 112, or the impurities may diffuse (or activate) at the high temperature (for example, 500 to 1000° C.).

Since both the wafer 152 and the preliminary membrane layer 112 may include the semiconductor material, the wafer 152 and the preliminary membrane layer 112 may be bonded through the high temperature diffusion process due to a difference between the doping concentration of the wafer 152 and the doping concentration of the preliminary membrane layer 112. During this bonding process, the hole barrier or the tunneling path may be induced due to a doping concentration difference between the wafer 152 and the preliminary membrane layer 112. Since the hole barrier or the tunneling path may be caused by random movement of the impurities including ion type without any uniformity, the hole barrier or the tunneling path may randomly generate in the preliminary membrane layer 112, to form the random arranged pores H.

Additionally, the preliminary membrane layer 112 may be thermally treated at a high temperature to generate intentional crystal defects in the preliminary membrane layer 112 to form the randomly arranged pores H. For example, the high temperature may be 500° C. to 1000° C., but is not limited to. A temperature of the treatment may vary depending on the material of the preliminary membrane layer 112.

For example, as the porous treatment 120, the ion implantation may be performed on the preliminary membrane layer 112 using various depths or various energies to apply intentional damages on the surface of the preliminary membrane layer 112 to form the randomly arranged pores H.

For example, the porous treatment 120 may include a process of etching (hereinafter, transcribing a pore pattern) the preliminary membrane layer 120 using a mask pattern (not shown) having random arranged porous H.

On the other hand, before or after the porous treatment, an adhesive layer may be formed on the backside of the wafer 152. The adhesive layer may be patterned in a form of a border portion to form an adhesive pattern 150a.

A center portion of a bottom surface of the wafer 152 may be removed to form a border portion 150. For example, the border portion 150 may correspond to the form of the adhesion pattern 150a disposed at the edge region of the bottom surface of the porous membrane 110 (see FIG. 3). The etching process of the wafer 152 for forming the border portion 150 may be performed while the wafer 152 is flipped. During the etching process of the wafer 152, due to the thickness of the wafer 152, the wafer 152 may be etched in a tapered manner. Accordingly, a width of the border portion 150 at a point at which the border potion 150 contacts the adhesion pattern 150a may be different from a width of the border portion 150 at a point at which the border potion 150 contacts the porous membrane 110.

FIG. 8 is a cross-sectional view illustrating a method of manufacturing an optical structure in accordance with example embodiments.

Referring to FIG. 8, a porous membrane layer 113 including randomly arranged pores H may be directly formed on an upper surface of the wafer 152.

For example, the porous membrane layer 113 including the randomly arranged pores H may be formed through an epitaxial growth process. During the epitaxial growth process, impurities (or dopants) may be doped in the porous membrane layer 113, causing a doping concentration difference between the porous membrane layer 113 and the wafer 152.

The doping concentration difference may result in a difference in Fermi level between the porous membrane layer 113 and the wafer 152 so that the hole barrier or the tunneling path causing pores H may be generated in the porous membrane 110. Furthermore, because the porous membrane layer 113 grown through the epitaxial process may have a crystalline state, the porous membrane layer 113 may cause intentional crystalline defects to generate the randomly arranged pores H. Alternatively, the porous membrane layer 113 may include a plurality of nanotubes or a plurality of nanowires. The plurality of nanotubes or the plurality of nanowires may include a material different from the material of the porous membrane layer 113 to generate the randomly arranged pores H in the membrane layer 113.

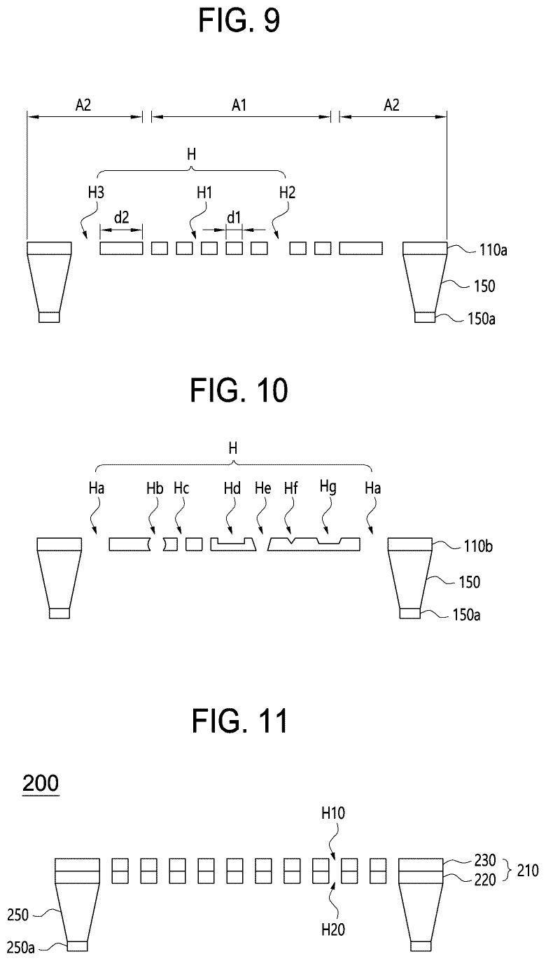

FIG. 9 is a cross-sectional view illustrating a pellicle structure in accordance with example embodiments.

Referring to FIG. 9, a porous membrane 110a of a pellicle structure may include a pore dense region A1 and a pore sparse region A2.

The randomly arranged pores H1 and H2 in the pore dense region A1 may be closely arranged with a first gap d1. On the other hand, the pores H3 arranged in the pore sparse region A2 may be arranged with a second gap d2, the second gap d2 being wider than the first gap d1.

In example embodiments, a width (or diameter) of the pores H1 and H2 arranged in the pore dense region A1 may be less than or equal to a width (or diameter) of the pores H3 arranged in the pore free region A2.

In example embodiments, the pore dense region A1 and the pore sparse region A2 may be set in consideration of a scattering of the previous optical structure. Furthermore, a location and a shape of the pores H1, H2, H3 may be changed by adjusting manufacture process variables, such as locations of the impurity implantation, a depth (energy) of the impurity implantation and a size of the impurity ions.

FIG. 10 is a cross-sectional view illustrating a pellicle structure in accordance with example embodiments.

Referring to FIG. 10, a porous membrane 110b of a pellicle structure may include a plurality of pores H having various depths and various cross-sectional structures. For example, some of the pores Ha, Hb, Hc and He of the plurality of pores H may have a depth that is substantially the same as a thickness of the porous membrane 110b. Pores Hd, Hf, and Hg of the plurality of pores (H) may have a depth that is less than the thickness of the membrane 110b.

Furthermore, the porous membrane 110b may include pores Ha, Hc, and Hd with a quadrangular cross-sectional structure, the pore Hb with a bulb cross-sectional structure, the pores He and Hg with a polygonal cross-sectional structure, such as a trapezoidal cross-sectional structure, and the pore Hf with a triangular cross-sectional structure. The cross-sectional structure of the pores Ha-Hg is not limited to the above structures and may vary.

FIG. 11 is a cross-sectional view illustrating a pellicle structure in accordance with example embodiments.

Referring to FIG. 11, a pellicle structure 200 of example embodiments may include a porous membrane 210 and a border portion 250.

The porous membrane 210 may include a plurality of porous membrane layers. For example, the porous membrane 210 may include a first porous membrane layer 230 and a second porous membrane layer 220 that are sequentially stacked.

For example, the second porous membrane layer 220 and the first porous membrane layer 230 may be sequentially stacked on top of the photomask. The first porous membrane layer 230 and the second porous membrane layer 220 may include a material capable of transmitting incident light, e.g., EUV passing through the photomask. For example, the first and second porous membrane layers 220 and 230 may include at least one of, but not limited to, single crystalline silicon, polysilicon, amorphous silicon, SiO2, SiC, SiN, SiOCN), SiON, and SiOC, a porous material layer, an impurity-containing material layer, a metal-containing material layer, and a block copolymer.

The first and second porous membrane layers 230 and 220 may be light transmissive but may have different material properties. For example, the first and second porous membrane layers 230 and 220 may have the same or different light transmittance. Further, the first and second porous membrane layers 230 and 220 may include different components and may be formed through different processes. The first and second porous membrane layers 230 and 220 may each include randomly arranged pores H10 and H20. The pores H10 of the first porous membrane layer 230 and the pores H20 of the second porous membrane layer 220 may be aligned along a vertical direction.

The border portion 250 may be disposed at a bottom surface edge of the porous membrane 210. In example embodiments, the border portion 250 may be, but is not limited to, a part of a wafer. When the border portion 250 is part of the wafer, the border portion 250 may be formed by partially removing the wafer.

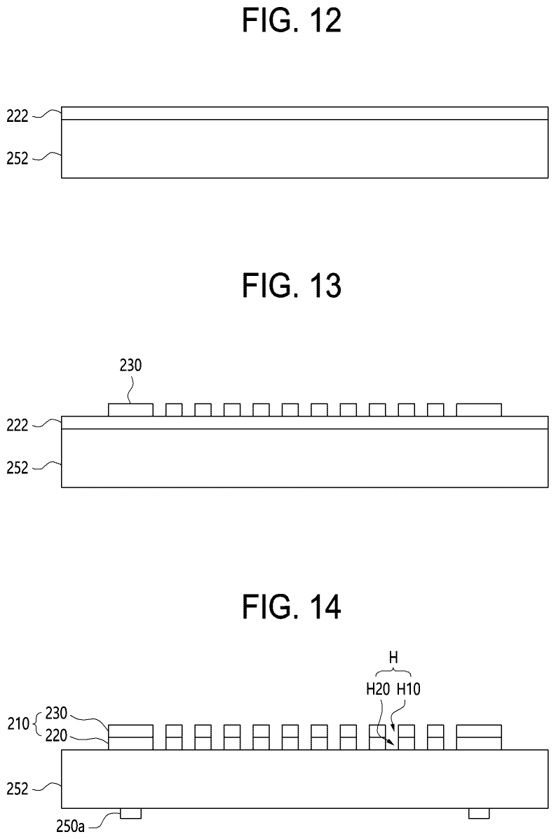

FIGS. 12 to 14 are cross-sectional views illustrating a method of manufacturing the pellicle structure in FIG. 11.

Referring to FIG. 12, a wafer 252 may be prepared. The wafer 252 may be formed into the border portion 250 by a subsequent process.

A preliminary membrane layer 222 may be formed on the wafer 252. The preliminary membrane layer 222 may include a material, for example, a light-transmitting material. For example, the preliminary membrane layer 222 may be a material having an etch selectivity ratio with respect to the wafer 252.

Referring to FIG. 13, a first porous membrane layer 230 may be formed on an upper surface of the preliminary membrane layer 222. For example, the random pores H10 may be generated based on the deposited first porous membrane layer 230. The first porous membrane layer 230 may include a layer formed through an epitaxial growth process utilizing impurities or including nanowires, as described above, but is not limited thereto.

Alternatively, the first porous membrane layer 230 may be subjected to a separate porous treatment after deposition such that random first pores H10 may be generated in the first porous membrane layer 230. The porous treatment may include, but is not limited to, a process for implanting and diffusing impurities at a high temperature to generate a hole barrier or a tunneling path in the membrane layer, a process for thermally treating at a high temperature to generate crystal defects in the membrane layer, a process for implanting impurities to generate damage to the surface of the membrane layer, and a process for transcribing a pore pattern into the membrane layer using a mask including randomly arranged openings.

Referring to FIG. 14, using the first porous membrane layer 230 as a mask, the preliminary membrane layer 222 may be patterned to form a second porous membrane layer 220 including randomly arranged second pores H20.

As the first porous membrane layer 230 may be utilized as a mask, a shape of the first pores H10 of the first porous membrane layer 230 may be transcribed into the second porous membrane layer 220. Accordingly, the first pores H10 and the second pores H20 may be connected in a vertical direction.

Referring to FIG. 14, after depositing an adhesive layer on a bottom surface of the wafer 252, the adhesive layer may be patterned to remain in a region where the border may be formed to form an adhesive pattern 250a.

Thereafter, after the wafer 252 with the adhesion pattern 250a formed may be flipped, the wafer 252 may be removed using the adhesion pattern 250a as a mask to form the border portion 250. By forming the border portion 250, the porous membrane 210 may be exposed to complete the pellicle structure 200 in FIG. 11.

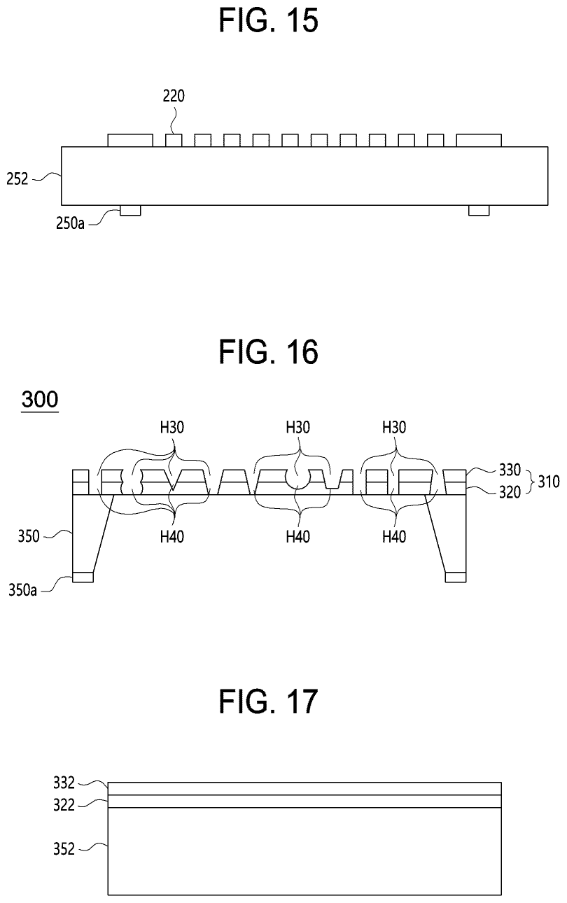

FIG. 15 is a cross-sectional view illustrating a method of manufacturing a pellicle structure in accordance with example embodiments.

Before etching the wafer 252 in FIG. 14 to form the border portion, the first porous membrane layer 230 may be removed, as shown in FIG. 15, to form the membrane of the pellicle structure with only the second porous membrane layer 220. Alternatively, it will be appreciated that the first porous membrane layer 230 may be left in place and might not be removed to form the pellicle structure.

FIG. 16 is a cross-sectional view illustrating a pellicle structure in accordance with example embodiments.

Referring to FIG. 16, a pellicle structure 300 of example embodiments may include a porous membrane 310 and a border portion 350.

The porous membrane 310 may include a first porous membrane layer 330 and a second porous membrane layer 320.

The first porous membrane layer 330 may be positioned on an upper surface of the second porous membrane layer 320. The first porous membrane layer 330 and the second porous membrane layer 320 may include a material capable of transmitting incident light, e.g., EUV, passing through the photomask. For example, the first and second porous membrane layers 330 and 320 may include at least one of, but not limited to, single crystalline silicon, polysilicon, amorphous silicon, SiO2, SiC, SiN, SiOCN), SiON, and SiOC, a porous material layer, an impurity-containing material layer, and a metal-containing material layer. The first and second porous membrane layers 330 and 320 may be the same or different materials.

The first and second porous membrane layers 330 and 320 may include randomly arranged pores H30 and H40, respectively. The first pores H30 arranged in the first porous membrane layer 330 and the second pores H40 arranged in the second porous membrane layer 320 may be aligned along a vertical direction. However, the first pores H30 and the second pores H40 may differ in at least one of a width, a shape and a depth.

The border portion 350 may be disposed at the edge of the bottom surface of the porous membrane 310. The bottom surface of the border portion 350 may be provided with an adhesive pattern 350a to be bonded with a photomask (not shown).

FIGS. 17 to 19 are cross-sectional views illustrating a method of manufacturing the pellicle structure in FIG. 16.

Referring to FIG. 17, a first preliminary membrane layer 322 and a second preliminary membrane layer 332 may be sequentially stacked on the upper surface of the wafer 352. The first preliminary membrane layer 322 and the second preliminary membrane layer 332 may be, for example, a light transmitting material.

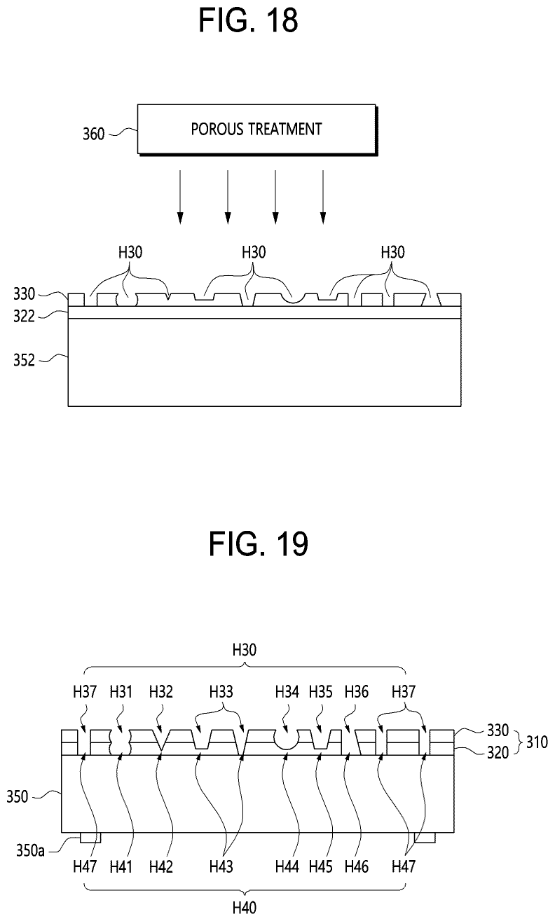

Referring to FIG. 18, the second preliminary membrane layer 332 may be subjected to a porous treatment 360 to form a first porous membrane layer 330. Through the porous treatment 360, the first porous membrane layer 330 may form a plurality of first pores H30 having various widths, various depths, and various cross-sectional structures. For example, the first pores H30 may have various shapes, such as a through structure, a groove structure having a depth that is shallower than a thickness of the second membrane layer 332, a quadrangular cross-sectional structure, a bulbous cross-sectional structure, a triangular cross-sectional structure, and the like.

In some cases, instead of the process for forming the second preliminary membrane layer 332 and the process for treating the second preliminary membrane layer 332, the first porous membrane layer 330 including the plurality of first pores H30 may be formed directly on the upper surface of the first preliminary membrane layer 322.

The porous treatment may include, but is not limited to, the heat treatment process, the high temperature diffusion process of impurities, or the impurity ion implantation/activation process, as described above.

Then, using the first porous membrane layer 330 as a mask, the first preliminary membrane layer 322 may be patterned to form the second porous membrane layer 320 including a plurality of second pores H40, as shown in FIG. 19.

As described above, because the plurality of first pores H30 have various widths, various depths, and various cross-sectional shapes, some of the plurality of second pores H40 transcribed from the plurality of first pores H30 may be located under the plurality of first pores H30 but may have a different structure than the plurality of first pores H30.

For example, through a patterning process, at least one of the second pores H41, H42, H43, and H45 of the plurality of second pores H40 may be formed to have a narrower width than the corresponding first pores H31, H32, H33, and H35.

Further, through the patterning process, at least one of the second pores H42, H44, and H45 of the plurality of second pores H40 may be formed to have a shallower depth than the corresponding first pores H32, H34, and H35. For example, when patterning the first preliminary membrane layer 322 to form first pores H32, H34, and H35, the first pores H30 of FIG. 18, corresponding to the first pores of FIG. 19, having a shallower depth than the first porous membrane layer 330 may be further etched to penetrate the first porous membrane layer 330 and to form a groove in the first preliminary membrane layer 322. Accordingly, the depth of the first pores H32, H34, and H35 may vary, and the second pores H42, H44, and H45 may be formed with a thickness that is less than the depth of the first pores H32, H34, and H35.

Further, at least one second pore H47 of the plurality of second pores H40 may be formed to have a width that is wider than that of the corresponding first pore H36.

Alternatively, at least one second pore H47 of the plurality of second pores H40 may have the same width as the corresponding first pore H37.

Thereafter, an adhesion pattern 350a may be formed on the bottom surface of the wafer 352. Using the adhesion pattern 350a, the central region of the wafer 352 may be removed to form the border portion 350.

As described in more detail above, according to some embodiments, the membrane may have the porous structure such that the pressure imbalance may not occur in the membrane. Accordingly, the deformation or the breakage of the membrane due to the pressure imbalance may be prevented. In particular, since the pores of the porous membrane may be irregularly arranged, the deformation of the exposure pattern due to regular scattering may be suppressed.

While the present invention has been described in detail with reference to preferred embodiments, the invention is not limited to the above embodiments but is capable of many modifications by those having ordinary skill in the art within the scope of the technical ideas of the invention.

What is claimed is:

1. An optical structure comprising:
a porous membrane including at least one membrane layer, the porous membrane including a plurality of pores that is randomly arranged, the porous membrane being light-transmissive; and
a border portion positioned at a bottom edge of the porous membrane to support the porous membrane.

2. The optical structure of claim 1, wherein the porous membrane comprises:
a first porous membrane layer including a plurality of first pores; and
a second porous membrane layer positioned below the first porous membrane layer and including a plurality of second pores.

3. The optical structure of claim 1, wherein each of the plurality of first pores corresponds to each of the plurality of second pores.

4. The optical structure of claim 3, wherein the plurality of first pores and the plurality of second pores have at least one of a quadrangular cross-section, a triangular cross-section, a bulbous cross-section and a polygonal cross-section.

5. The optical structure of claim 4, wherein each second pore differs in at least one of a width, a depth, and a shape with respect to each corresponding first pore.

6. The optical structure of claim 1, wherein the porous membrane layer comprises pores having a depth substantially the same as a thickness of the porous membrane layer and pores having a depth less than the thickness of the membrane layer.

7. The optical structure of claim 1, wherein the plurality of pores has at least one of a linear planar structure, a circular planar structure and a polygonal planar structure.

8. A method of manufacturing an optical structure, the method comprising:
forming a porous membrane over an upper surface of a wafer; and
etching a central region of the wafer to form a border portion to support the porous membrane,
wherein the porous membrane includes a plurality of pores that is randomly arranged.

9. The method of claim 8, wherein the forming of the porous membrane comprises depositing the porous membrane over the wafer through an epitaxial growth process while doping impurities to generate a hole barrier or a tunneling path in the porous membrane.

10. The method of claim 8, wherein forming the porous membrane comprises:
forming a preliminary membrane layer over an upper surface of the wafer; and
porously treating the preliminary membrane layer to form the plurality of pores,
wherein the porously treating of the preliminary membrane comprises at least one of a process for ion implanting and diffusing impurities at a high temperature to generate a hole barrier or a tunneling path in the preliminary membrane layer, a process for thermally treating at a high temperature to generate crystal defects in the preliminary membrane layer, a process for implanting impurities to form damage on a surface of the preliminary membrane layer, and a process for transcribing pore patterns into the preliminary membrane layer using a mask with the plurality of pores that is randomly arranged.

11. The method of claim 8, wherein forming the porous membrane comprises:
forming a first preliminary membrane layer over an upper surface of the wafer;
forming a first porous membrane layer including a plurality of first pores randomly arranged, an upper surface of the first preliminary membrane layer; and
etching the first preliminary membrane layer, using the first porous membrane layer as a mask, to form a second porous membrane layer including a plurality of second pores that is randomly arranged.

12. The method of claim 11, wherein the forming of the first porous membrane layer comprises epitaxially growing the wafer while doping impurities to generate a hole barrier or a tunneling path in the first porous membrane layer.

13. The method of claim 11, wherein the forming of the first porous membrane layer comprises:
forming a second preliminary membrane layer over an upper surface of the first preliminary membrane layer; and
porously treating the second preliminary membrane layer,
wherein the porously treating of the second preliminary membrane comprises at least one of a process for ion implanting and diffusing impurities at a high temperature to generate a hole barrier or a tunneling path in the preliminary membrane layer, a process for thermally treating at a high temperature to generate crystal defects in the preliminary membrane layer, a process for implanting impurities to form damage on a surface of the preliminary membrane layer, and a process for transcribing pore patterns into the preliminary membrane layer using a mask with the plurality of pores that is randomly arranged.

14. The method of claim 11, wherein further comprising selectively removing the first porous membrane layer after forming the second porous membrane layer including the plurality of second pores that is randomly arranged.

15. The method of claim 8, wherein forming the border portion comprises:
forming an adhesive pattern over an edge portion of a bottom surface of the wafer; and
etching the wafer using the adhesion pattern as a mask,
wherein, when the wafer is etched, the wafer is flipped so that the porous membrane is facing downward.

16. A method of manufacturing an optical structure, the method comprising:
providing a support layer;
forming a first preliminary membrane layer over an upper surface of the support layer; and
porously treating the first preliminary membrane layer to form a porous membrane including a plurality of pores that is randomly arranged, wherein at least one of a cross-sectional structure and a planar structure of a pore, among cross-sectional structures of the plurality of pores and planar structures of the plurality of pores, is non-uniform,
wherein porously treating the preliminary membrane comprises at least one of a process for ion implanting and diffusing impurities at a high temperature to generate a hole barrier or a tunneling path in the preliminary membrane layer, a process for thermally treating at a high temperature to generate crystal defects in the preliminary membrane layer and a process for implanting impurities to form damage on a surface of the second preliminary membrane layer.

17. The method of claim 16, further comprising removing the support layer to remain at an edge of the porous membrane, thereby forming a border portion.
